(19) United States
(12) Patent Application Publication
(10) Pub. No.: US 2019/0074819 A1
(43) Pub. Date: Mar. 7, 2019

(54) FILTER WITH SURFACE ACOUSTIC WAVE DEVICE FOR CARRIER AGGREGATION SYSTEM

(71) Applicant: Skyworks Solutions, Inc., Woburn, MA (US)

(72) Inventors: Rei Goto, Osaka-Shi (JP); Keiichi Maki, Suita-Shi (JP); Yosuke Hamaoka, Suita-Shi (JP)

(21) Appl. No.: 16/104,063

(22) Filed: Aug. 16, 2018

Related U.S. Application Data
(60) Provisional application No. 62/547,610, filed on Aug. 18, 2017.

(51) Int. Cl. H03H 9/64; H03H 9/02; H03H 9/145; H03H 9/25; H03H 9/72; H03F 3/19; H03F 3/21; H04J 1/04

(52) U.S. Cl. CPC H03H 9/6489; H03H 9/02574; H03H 9/02559; H03H 9/02551; H03H 9/145; H03H 9/25; H03F 2200/294; H03H 9/02834; H03F 3/19; H03F 3/21; H04J 1/045; H03F 2200/451; H03H 9/725

(57) ABSTRACT

Aspects of this disclosure relate to a filter for a carrier aggregation system. The filter is configured to pass a first band of a carrier aggregation signal. The filter includes a surface acoustic wave device that includes a quartz substrate, an interdigital transducer electrode, and a lithium-based piezoelectric layer positioned between the quartz substrate and the interdigital transducer electrode. The surface acoustic wave device is configured to suppress a higher order spurious mode corresponding to a second band of the carrier aggregation signal.

### CROSS REFERENCE TO PRIORITY APPLICATION

Any and all applications for which a foreign or domestic priority claim is identified in the Application Data Sheet as filed with the present application are hereby incorporated by reference under 37 CFR § 1.57. This application claims the benefit of priority under 35 U.S.C. § 119(e) of U.S. Provisional Patent Application No. 62/547,610, filed Aug. 18, 2017 and titled “FILTER WITH SURFACE ACOUSTIC WAVE DEVICE FOR CARRIER AGGREGATION SYSTEM,” the disclosure of which is hereby incorporated by reference in its entirety herein.

### BACKGROUND

### Technical Field

Embodiments of this disclosure relate to a filter with a surface acoustic wave device.

### Description of Related Technology

An acoustic wave filter can include a plurality of resonators arranged to filter a radio frequency signal. Example acoustic wave filters include surface acoustic wave (SAW) filters and bulk acoustic wave (BAW) filters. A film bulk acoustic resonator (FBAR) filter is an example of a BAW filter.

Acoustic wave filters can be implemented in radio frequency electronic systems. For instance, filters in a radio frequency front end of a mobile phone can include acoustic wave filters. A plurality of acoustic wave filters can be arranged as a multiplexer. For example, two surface acoustic wave filters can be arranged as a duplexer.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a filter for a carrier aggregation system. The filter includes a surface acoustic wave device that includes a quartz substrate, an interdigital transducer electrode, and a lithium-based piezoelectric layer positioned between the quartz substrate and the interdigital transducer electrode. The surface acoustic wave device is configured to suppress a higher order spurious mode corresponding to a second band of a carrier aggregation signal. The filter is configured to pass a first band of the carrier aggregation signal.

The quartz substrate can have a cut angle in a range from 20° to 52°, in which the cut angle is rotated Y-cut X-propagation.

The lithium-based piezoelectric layer can be a lithium tantalate layer. The surface acoustic wave device is configured to generate a surface acoustic wave having a wavelength of λ and a thickness of the lithium tantalate layer can be in a range from 0.15 λ to 1.4 λ. The lithium tantalate layer can have a cut angle in a range from 10° to 50°.

The filter can be a transmit filter, in which the first band is a transmit band and the second band is a receive band. The filter can be a receive filter, in which the first band is a receive band and the second band is a transmit band.

The filter can be configured to suppress another higher order spurious mode corresponding to a third band of the carrier aggregation signal.

The surface acoustic wave device can be configured to operate in a shear-horizontal mode. The surface acoustic wave device can have a sound velocity in a range from 3,800 meters per second to 4,200 meters per second.

The lithium-based piezoelectric layer can be bonded to the quartz substrate.

The surface acoustic wave device can further include an additional layer disposed between the lithium-based piezoelectric layer and the quartz substrate, in which the additional layer configured to cause a quality factor of the surface acoustic wave device to be increased.

Another aspect of this disclosure is a filter assembly for a carrier aggregation system. The filter assembly including a first filter and a second filter. The first filter includes a surface acoustic wave device that includes a quartz substrate, an interdigital transducer electrode, and a lithium-based piezoelectric layer positioned between the quartz substrate and the interdigital transducer electrode. The surface acoustic wave device is configured to suppress a higher order spurious mode corresponding to a second band of a carrier aggregation signal. The first filter is configured to pass a first band of the carrier aggregation signal. The second filter is configured to pass a second band of the carrier aggregation signal.

The first filter can be a transmit filter and the second filter can be a receive filter. The first filter can be a receive filter and the second filter can be a transmit filter. The filter assembly can include a multiplexer that includes the first filter and the second filter.

Another aspect of this disclosure is a carrier aggregation system that includes a frequency multiplexing circuit having a terminal at which a carrier aggregation signal is provided and a multiplexer in communication with the frequency multiplexing circuit. The multiplexer includes filters coupled to a common node. The filters include a first filter configured to pass a first band of the carrier aggregation signal. The first filter includes a surface acoustic wave device that includes a quartz substrate, an interdigital transducer electrode, and a lithium-based piezoelectric layer positioned between the quartz substrate and the interdigital transducer electrode. The surface acoustic wave device is configured to suppress a higher order spurious mode corresponding to a second band of the carrier aggregation signal.

The frequency multiplexing circuit can be a diplexer. The multiplexer can be a duplexer. The carrier aggregation system can further include a power amplifier and a switch coupled between the power amplifier and the first filter.

Another aspect of this disclosure is a packaged module for a carrier aggregation system. The packaged module includes a first filter configured to pass a first band of the carrier aggregation signal, a second filter configured to filter the carrier aggregation signal, and a package enclosing the first filter and the second filter. The first filter includes a surface acoustic wave device that includes a quartz substrate, an interdigital transducer electrode, and a lithium tantalate layer positioned between the quartz substrate and the interdigital transducer electrode. The surface acoustic wave device is configured to suppress a higher order spurious mode corresponding to a second band of a carrier aggregation signal.

The packaged module can further include a power amplifier configured to provide a radio frequency signal to at least one of the first filter or the second filter. The packaged module can include a multi-throw switch coupled to the first filter and the second filter. The multi-throw switch can have a single throw coupled to a common node and the first filter can be coupled to the second filter at the common node. The multi-throw switch can have a first throw coupled to the first filter and a second throw coupled to the second filter.

Another aspect of this disclosure is a wireless communication device that includes an antenna configured to receive a carrier aggregation signal and a multiplexer in communication with the antenna. The multiplexer includes filters coupled to a common node. The filters include a first filter configured to pass a first band of the carrier aggregation signal and a second filter configured to filter the carrier aggregation signal. The first filter includes a surface acoustic wave device that includes a quartz substrate, an interdigital transducer electrode, and a lithium tantalate layer positioned between the quartz substrate and the interdigital transducer electrode. The surface acoustic wave device is configured to suppress a higher order spurious mode corresponding to a second band of the carrier aggregation signal.

The wireless communication device can be a mobile phone. The wireless communication device can further include a frequency multiplexing circuit coupled between the common node and the antenna. The frequency multiplexing circuit can be a diplexer or a triplexer. The wireless communication device can further include an antenna switch coupled between the common node and the antenna. The antenna can be a primary antenna.

Another aspect of this disclosure is a method of filtering a carrier aggregation signal. The method includes passing a first band of the carrier aggregation signal with a filter that includes a surface acoustic wave device. The surface acoustic wave device includes a quartz substrate, an interdigital transducer electrode, and a lithium-based piezoelectric layer positioned between the quartz substrate and the interdigital transducer electrode. The method also includes suppressing a higher order spurious mode corresponding to a second band of the carrier aggregation signal with the first filter.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1A is a graph of transfer coefficient versus frequency for a filter with undesirable attenuation for a frequency band associated with a carrier aggregation signal.

FIG. 1B is a graph of transfer coefficient versus frequency for a filter with desirable attenuation for a frequency band associated with a carrier aggregation signal.

FIG. 2A is a graph of transfer coefficient versus frequency for a filter with undesirable attenuation for a frequency band associated with a carrier aggregation signal with 3 carriers.

FIG. 2B is a graph of transfer coefficient versus frequency for a filter with desirable attenuation for a frequency band associated with a carrier aggregation signal with 3 carriers.

FIG. 3A is a cross sectional view of a surface acoustic wave device according to an embodiment.

FIGS. 3B to 3E are graphs associated with a quartz cut angle sweep for various lithium tantalate layer thicknesses of the surface acoustic wave device of FIG. 3A. FIG. 3B is a graph of Qp versus quartz cut angle. FIG. 3C is a graph of Qs versus cut angle. FIG. 3C is a graph of electromechanical coupling coefficient (k²) versus cut angle. FIG. 3D is a graph of temperature coefficient of frequency (TCF) versus cut angle.

FIGS. 3F to 3I are graphs associated with a quartz cut angle sweep for various lithium tantalate layer thicknesses of the surface acoustic wave device of FIG. 3A, corresponding to a different propagation angle for quartz than for FIGS. 3B to 3E. FIG. 3F is a graph of Qp versus quartz cut angle. FIG. 3G is a graph of Qs versus cut angle. FIG. 3H is a graph of k² versus cut angle. FIG. 3I is a graph of TCF versus cut angle.

FIG. 3J is a graph of quality factor versus lithium tantalate cut angle for the surface acoustic wave device of FIG. 3A.

FIG. 3K is a graph of electromechanical coupling coefficient versus lithium tantalate cut angle for the surface acoustic wave device of FIG. 3A.

FIG. 4 is a cross sectional view of another surface acoustic wave device.

FIG. 5 is a cross sectional view of another surface acoustic wave device.

FIG. 6A is a graph of a frequency response for the surface acoustic wave devices of FIGS. 3A, 4, and 5.

FIG. 6B is a graph of electromechanical coupling coefficient (k²) versus frequency for the surface acoustic wave devices of FIGS. 3A, 4, and 5.

FIG. 6C is a graph of quality factor versus frequency for the surface acoustic wave devices of FIGS. 3A, 4, and 5.

FIG. 7A is a graph of transmission characteristics for the surface acoustic wave devices of FIGS. 3A, 4, and 5.

FIG. 7B is a graph of reflection characteristics for the surface acoustic wave devices of FIGS. 3A, 4, and 5.

FIG. 8A is a graph of Qs versus cut angle of lithium tantalate for the surface acoustic wave devices of FIGS. 3A, 4, and 5.

FIG. 8B is a graph of Qp versus cut angle of lithium tantalate for the surface acoustic wave devices of FIGS. 3A, 4, and 5.

FIG. 8C is a graph of electromechanical coupling coefficient versus cut angle of lithium tantalate for the surface acoustic wave devices of FIGS. 3A, 4, and 5.

FIG. 9A is a graph of Qs versus cut angle of quartz for the surface acoustic wave device of FIG. 3A.

FIG. 9B is a graph of Qp versus cut angle of quartz for the surface acoustic wave device of FIG. 3A.

FIG. 9C is a graph of electromechanical coupling coefficient versus cut angle of quartz for the surface acoustic wave device of FIG. 3A.

FIGS. 10A to 10E are graphs associated with a lithium tantalate thickness sweep for the surface acoustic wave device of FIG. 3A. FIG. 10A illustrates ΔZ_{SH} and ΔZ_{SP} in a frequency response. FIG. 10B shows impedance ratios ΔZ_{SH} and ΔZ_{SP} versus thickness of a lithium tantalate layer. FIG. 10C is graph of Qs versus thickness of the lithium tantalate layer of the surface acoustic wave devices of FIGS. 3A, 4, and 5. FIG. 10D is graph of Qs versus thickness of the lithium tantalate layer of the surface acoustic wave devices of FIGS. 3A, 4, and 5. FIG. 10E is graph of k² versus thickness of the lithium tantalate layer of the surface acoustic wave devices of FIGS. 3A, 4, and 5.

FIGS. 11A to 11C are graphs associated with a lithium tantalate propagation angle sweep for the surface acoustic wave devices of FIGS. 3A, 4, and 5. FIG. 11A is a graph of Qs versus propagation angle. FIG. 11B is a graph of Qp versus propagation angle. FIG. 11C is a graph of k² versus propagation angle.

FIG. 12 is a graph of sound velocity versus lithium tantalate thickness for the surface acoustic wave devices of FIGS. 3A, 4, and 5.

FIG. 13 is a cross sectional view of a surface acoustic wave device according to an embodiment.

FIGS. 14A to 14D are graphs of parameters of the surface acoustic wave device of FIG. 13. FIG. 14A is a graph of silicon dioxide thickness versus TCF. FIG. 14B is a graph of silicon dioxide thickness versus Qs. FIG. 14C is a graph of silicon dioxide thickness versus Qp. FIG. 14D is a graph of silicon dioxide thickness versus k².

FIG. 15 is a cross sectional view of a surface acoustic wave device according to an embodiment.

FIG. 16A is a cross sectional view of a surface acoustic wave device according to an embodiment.

FIG. 16B is a graph comparing electromechanical coupling coefficient versus cut angle of a lithium-based piezoelectric layer for the surface acoustic wave devices of FIGS. 3A and 16A.

FIG. 17A is a schematic diagram of a carrier aggregation system according to an embodiment.

FIG. 17B is a schematic diagram of a carrier aggregation system according to an embodiment.

FIG. 17C is a schematic diagram of a carrier aggregation system according to an embodiment.

FIG. 17D is a schematic diagram of a carrier aggregation system according to an embodiment.

FIG. 18A is a schematic block diagram of a module that includes a filter in accordance with one or more embodiments.

FIG. 18B is a schematic block diagram of a module that includes a filter in accordance with one or more embodiments.

FIG. 19 is a schematic block diagram of a wireless communication device that includes a filter in accordance with one or more embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

In carrier aggregation systems, it can be challenging to achieve a relatively high quality factor (Q) and higher order spurious mode suppression in a surface acoustic wave filter.

Some approaches to this challenge involve an acoustic wave device with a relatively thin lithium tantalate (LT) layer bonded on a relatively high impedance substrate (e.g., a silicon substrate, an aluminum nitride substrate, or a sapphire substrate). Such approaches can achieve relatively high Q. However, such approaches can excite relatively strong higher order spurious modes. The spurious modes can make it difficult to achieve a specified attenuation on a higher frequency range. This can present issues in carrier aggregation systems. For instance, multiplexers, such as duplexers or quadplexers, can fail to meet attenuation specifications for carrier aggregation applications with such spurious modes.

Aspects of this disclosure are related to a surface acoustic wave device with a multi-layer piezoelectric substrate that includes a lithium-based piezoelectric layer, such as a lithium tantalate layer or a lithium niobate layer, and a quartz substrate to provide a relatively high Q and to suppress higher order spurious modes. The surface acoustic wave device can include a relatively thin lithium tantalate layer bonded on a quartz substrate. A higher order spurious mode can be suppressed by leakage into a crystal cut angle. The quartz cut angle can be in a range from 20° to 52° on R-rotated YX-quartz. The thickness of the lithium tantalate layer can be in a range from 0.15 λ to 1.4 λ, in which λ is a wavelength of a surface acoustic wave generated by the surface acoustic wave device.

By using the quartz as a substrate instead of certain relatively high impedance substrates, a higher order spurious mode can be leaked into a substrate side. This can be due to an anisotropic feature of quartz. Quartz can behave as a high impedance substrate at limited crystal cut angles. Accordingly, the Q of a surface acoustic wave device that includes a lithium tantalate layer over a quartz substrate can improve relative to other devices by trapping an acoustic wave in the lithium tantalate layer. Certain high impedance substrates (e.g., a silicon substrate, an aluminum nitride substrate, or a sapphire substrate), can trap an acoustic wave in a lithium tantalate layer. However, at the same time, higher order spurious mode responses can be trapped in the lithium tantalate layer with such high impedance substrates. Accordingly, higher order spurious responses can appear on filter response in such circumstances. Bulk wave velocity of quartz is less than other high impedance materials, such as silicon, aluminum nitride, and sapphire. Accordingly, a higher order spurious mode response can leak into quartz more than for the other high impedance materials. The Q factor associated with a higher mode spurious response can be decreased by leakage in accordance with the principles and advantages discussed herein, and spurious mode impact on filter response can be suppressed. Temperature coefficient of frequency (TCF) can also be improved by using lithium tantalate over quartz relative to only using lithium tantalate.

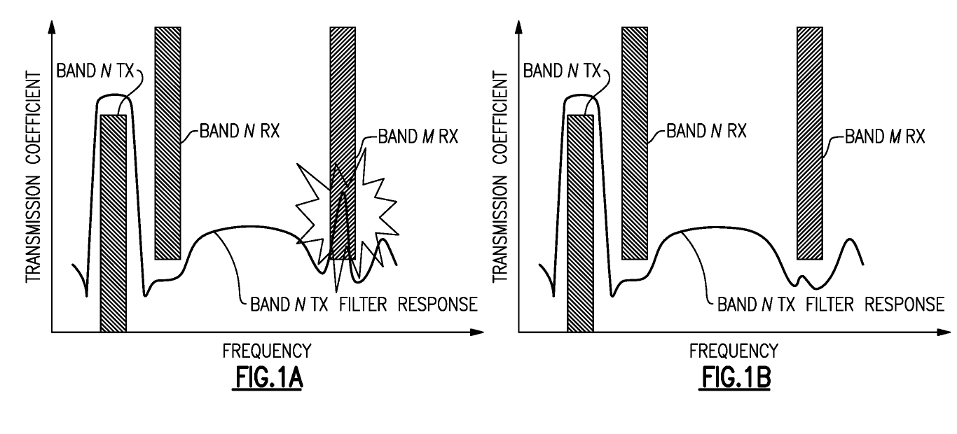

FIG. 1A is a graph of transfer coefficient versus frequency for a filter with undesirable attenuation for a frequency band associated with a carrier aggregation signal. This graph corresponds to a 2 band carrier aggregation case in which bands N and M are aggregated. For instance, a carrier aggregation signal can aggregate Band 1 and Band 3, in which Band 1 has a transmit band from 1920 megahertz (MHz) to 1980 MHz and a receive band from 2110 MHz to 2170 MHz and Band 3 has a transmit band from 1710 MHz to 1785 MHz and a receive band from 1805 MHz to 1880 MHz. The filter corresponding to the graph of FIG. 1A is a transmit filter configured to pass a Band N transmit frequency band. As shown in FIG. 1A, the frequency response of this filter provides an insufficient attenuation corresponding to a Band M receive frequency band for certain applications.

FIG. 1B is a graph of transfer coefficient versus frequency for a filter with desirable attenuation for a frequency band associated with a carrier aggregation signal. The filter corresponding to the graph of FIG. 1B is a transmit filter configured to pass a Band N transmit frequency band. As shown in FIG. 1B, this filter has a desirable attenuation corresponding to a Band M receive frequency band. Accordingly, the filter corresponding to the graph of FIG. 1B can be used for carrier aggregation with Bands N and M.

Filters in accordance with the principles and advantages discussed herein can achieve frequency responses like the frequency response shown in FIG. 1B. The graph of FIG. 1A illustrates a drawback of previous approaches associated with a lithium tantalate layer bonded on a relatively high impedance substrate discussed above.

While FIGS. 1A and 1B illustrates frequency responses of transmit filters, any suitable principles and advantages discussed herein can be implemented in receive filters. For carrier aggregation signals with Bands N and M, it can be desirable to have a relatively high attenuation for a Band M receive frequency band in a Band N transmit filter. Similarly, for carrier aggregation signals with Bands N and M, it can be desirable to have a relatively high attenuation for Band M transmit frequency band in a Band N receive filter.

FIGS. 1A and 1B relate to a 2-band carrier aggregation case. Any suitable principles and advantages discussed herein can be applied to carrier aggregation cases with 3 or more bands.

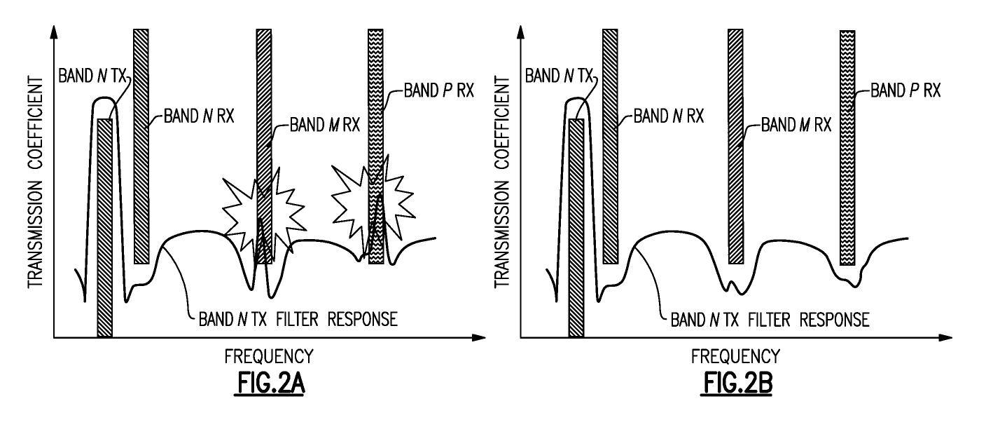

FIG. 2A is a graph of transfer coefficient versus frequency for a filter with undesirable attenuation for a frequency band associated with a carrier aggregation signal with 3 carriers. This graph corresponds to a 3-band carrier aggregation case in which bands N, M, and P are aggregated. For instance, a carrier aggregation signal can aggregate Band 1, Band 3, and Band 7. Band 1 can have a transmit band from 1920 MHz to 1980 MHz and a receive band from 2110 MHz to 2170 MHz, Band 3 can have a transmit band from 1710 MHz to 1785 MHz and a receive band from 1805 MHz to 1880 MHz, and Band 7 can have a transmit band from 2500 MHz to 2570 MHz and a receive band from 2620 MHz to 2690 MHz. The filter corresponding to the graph of FIG. 2A is a transmit filter configured to pass a Band N transmit frequency band. As shown in FIG. 2A, the frequency response of this filter can provide an insufficient attenuation corresponding to a Band M receive frequency band and a Band P receive frequency band for certain applications.

FIG. 2B is a graph of transfer coefficient versus frequency for a filter with desirable attenuation for a frequency band associated with a carrier aggregation signal with 3 carriers. The filter corresponding to the graph of FIG. 2B is a transmit filter configured to pass a Band N transmit frequency band. As shown in FIG. 2B, this filter has a desirable attenuation corresponding to a Band M receive frequency band and a Band P receive frequency band. Filters in accordance with the principles and advantages discussed herein can achieve frequency responses like the frequency response shown in FIG. 2B.

For carrier aggregation signals with Bands N, M, and P, it can be desirable to have a relatively high attenuation for a Band M receive frequency band and a Band P receive frequency band in a Band N transmit filter. Similarly, for carrier aggregation signals with Bands N, M, and P, it can be desirable to have a relatively high attenuation for Band M transmit frequency band and a Band P transmit frequency band in a Band N receive filter.

To achieve frequency responses like those shown in FIG. 1A and 2B, filters can include surface acoustic wave devices disclosed herein. Moreover, surface acoustic wave devices disclosed herein can be implemented in filters having any other suitable frequency responses.

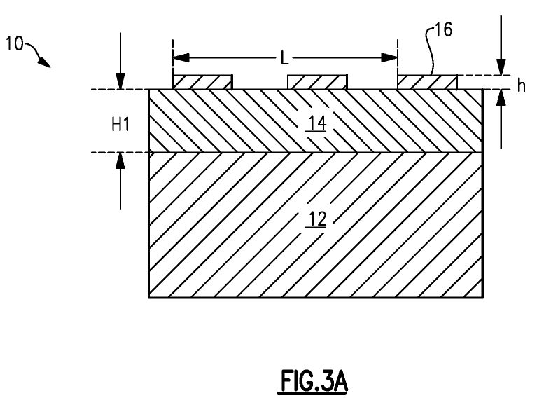

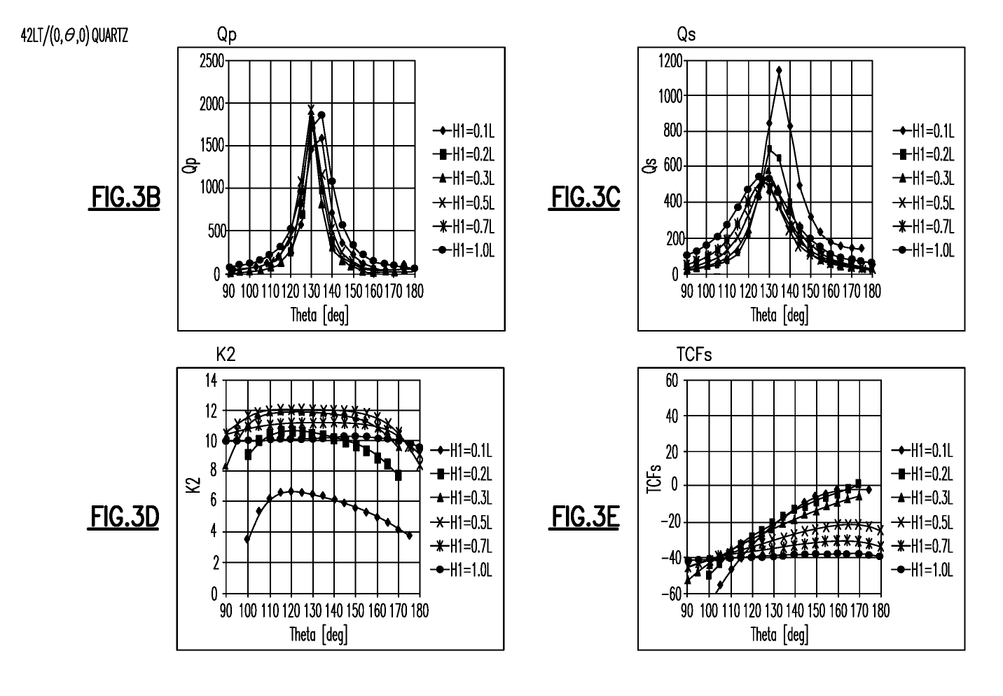

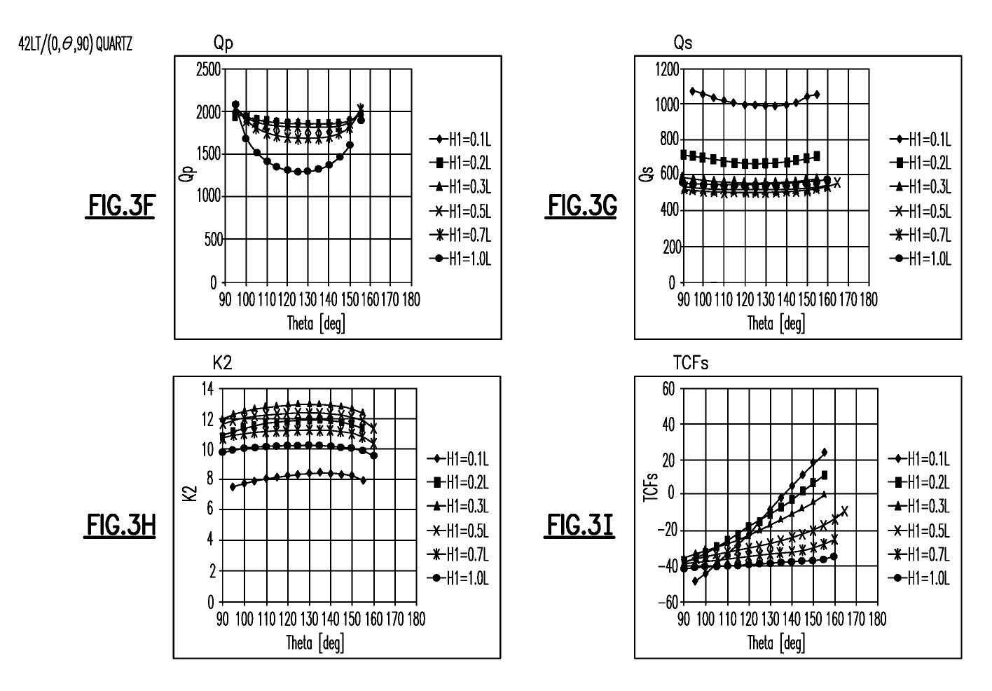

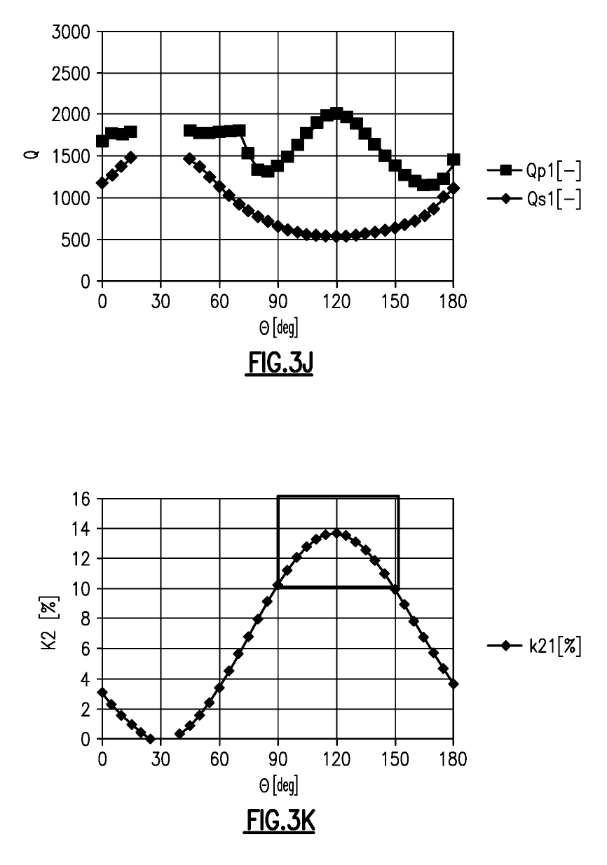

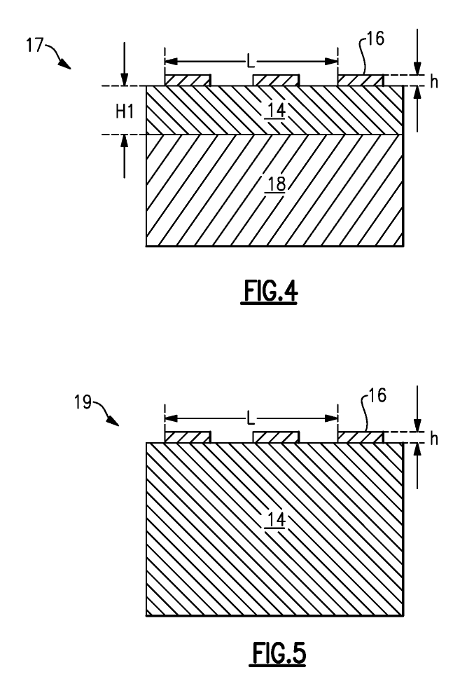

FIG. 3A is a cross sectional view of a surface acoustic wave device 10 according to an embodiment. The surface acoustic wave device 10 includes a quartz substrate 12, a lithium tantalate (LiTaO₃) layer 14 having a thickness H1, and an interdigital transducer (IDT) electrode 16 having a thickness h and pitch L. The surface acoustic wave device 10 can be implemented in a filter arranged to filter a carrier aggregation signal. Such a filter can pass a first band of the carrier aggregation signal and suppress a higher order spurious mode corresponding to a second band of the carrier aggregation signal. The surface acoustic wave device 10 can be configured to operate in a shear-horizontal (SH) mode.

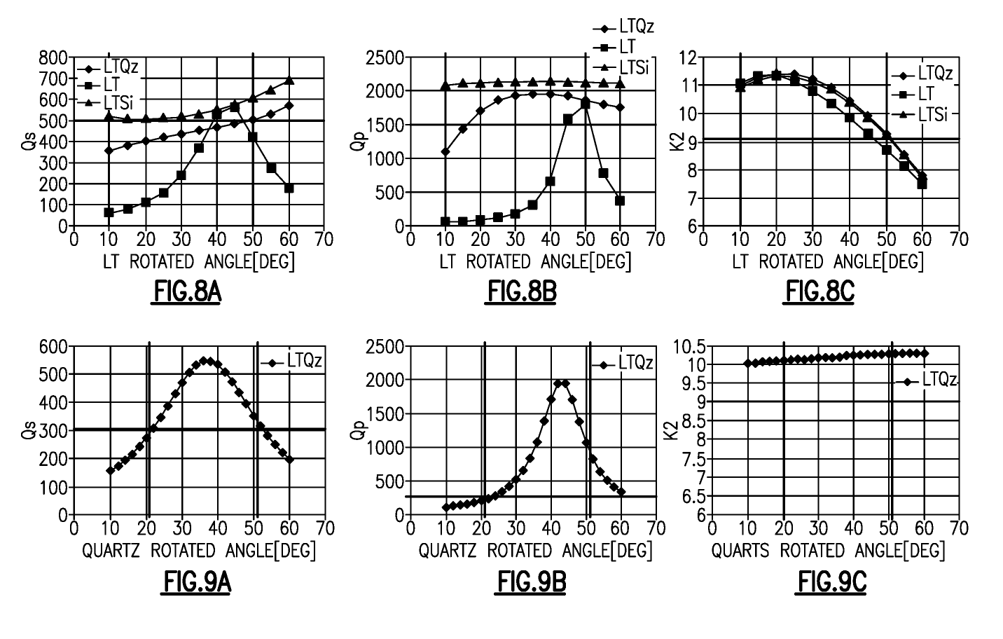

The quartz substrate 12 can have a cut angle in a range from 20° to 52°. As used herein, a “cut angle” of N° refers to an N° rotated Y-cut in a Y-cut X-propagation piezoelectric layer. Accordingly, for a piezoelectric layer with Euler angles (φ, θ, Ψ), the “cut angle” in degrees can be 0 minus 90°. The surface acoustic wave device can generate a surface acoustic wave having a wavelength of λ and the thickness H1 of the lithium tantalate layer 14 can be in a range from 0.15 λ to 1.4 λ. In some instances, the thickness H1 of the lithium tantalate layer 14 can be in a range from 0.2 λ to 1.2 λ. The lithium tantalate layer 14 can have a cut angle in a range from 10° to 50°. As shown in FIG. 8C, this cut angle range can provide desirable k² values. In some applications, the lithium tantalate layer 14 can have a cut angle in a range from 40° to 50°. The lithium tantalate layer 14 can be bonded to the quartz substrate 12.

FIGS. 3B to 3E are graphs associated with a quartz cut angle sweep for various lithium tantalate layer thicknesses H1 of the surface acoustic wave device 10. These graphs correspond to the surface acoustic wave device 10 in which the lithium tantalate layer 14 is 42° Y-X LT having a thickness H1 and the quartz substrate 12 has Euler angles of (0, θ, 0). The thickness H1 of the lithium tantalate layer 14 is represented in units of λ, in which k is a wavelength of a surface acoustic wave generated by the surface acoustic wave device 10. λ can be represented by “L”. These graphs indicate that quartz with a cut angle in a range from 20° to 52°, which corresponds to 0 being in a range from 110° to 142°, can be desirable. FIG. 3B indicates that a quality factor at anti-resonance (Qp) has a peak around θ=130° for various thicknesses of the lithium tantalate layer 14. FIG. 3C indicates that a quality factor at resonance (Qs) has a peak around θ=130° for various thicknesses of the lithium tantalate layer 14. FIG. 3D indicates that an electromechanical coupling coefficient k² has a maximum when the thickness H1 of the lithium tantalate layer 14 is around 0.3 λ to 0.5 λ. FIG. 3E plots TCF versus θ for various thicknesses H1 of the lithium tantalate layer 14.

FIGS. 3F to 3I are graphs associated with a quartz cut angle sweep for various lithium tantalate layer thicknesses H1 of the surface acoustic wave device 10. These graphs correspond to a different propagation angle for quartz than for FIGS. 3B to 3E. FIGS. 3F to 31 correspond to the surface acoustic wave device 10 in which the lithium tantalate layer 14 is 42° Y-X LT having a thickness H1 and the quartz substrate 12 has Euler angles of (0, θ, 90°). FIG. 3F indicates that Qp is relatively stable for a thinner lithium tantalate layer 14. FIG. 3G indicates that Qs is bigger for a relatively thinner lithium tantalate layer 14. FIG. 3H indicates that an electromechanical coupling coefficient k² has a maximum when the thickness H1 of the lithium tantalate layer 14 is around 0.3 λ. FIG. 3H also indicates that the electromechanical coupling coefficient k² is lower for a relatively thinner lithium tantalate layer 14. FIG. 3I indicates that TCF can be improved when the quartz substrate 12 has a propagation angle of 90° relative to when the quartz substrate 12 has a propagation angle of 0°.

FIGS. 3J to 3K are graphs associated with a lithium tantalate cut angle sweep for the surface acoustic wave device 10. These graphs correspond to the surface acoustic wave device 10 in which the lithium tantalate layer 14 has Euler angles of (0, θ, 0) and a thickness H1=0.3 λ, the quartz substrate 12 has Euler angles of (0, 132, 90), and the IDT electrode 16 is aluminum having a thickness of 0.08 λ. FIG. 3J is a graph of quality factor versus lithium tantalate cut angle for the surface acoustic wave device 10 of FIG. 3A. FIG. 3K is a graph of k² versus lithium tantalate cut angle for the surface acoustic wave device of FIG. 3A. As shown in FIG. 3K, k² can have a peak at about θ=120°. FIG. 3K indicates that it can be preferable for the cut angle of the lithium tantalate layer 14 to be in a range from about 90° to 150°.

Referring back to FIG. 3A, the IDT electrode 16 can be an aluminum IDT electrode. IDT electrode material can include titanium (Ti), gold (Au), silver (Ag), copper (Cu), platinum (Pt), tungsten (W), molybdenum (Mo), ruthenium (Ru), or any suitable combination thereof. For instance, the IDT electrode 16 can include aluminum and molybdenum in certain applications

FIG. 4 is a cross sectional view of a surface acoustic wave device 17. The surface acoustic wave device 17 includes a silicon substrate 18, a lithium tantalate layer 14 having a thickness H1, and an IDT electrode 16 having a thickness h and pitch L.

FIG. 5 is a cross sectional view of a surface acoustic wave device 19. The surface acoustic wave device 19 includes a lithium tantalate layer 14 and an IDT electrode 16 having a thickness h and pitch L. The lithium tantalate layer 14 can be sufficiently thick to ignore a bottom reflection effect. For example, the thickness of the lithium tantalate layer 14 is larger than 20×, in certain applications.

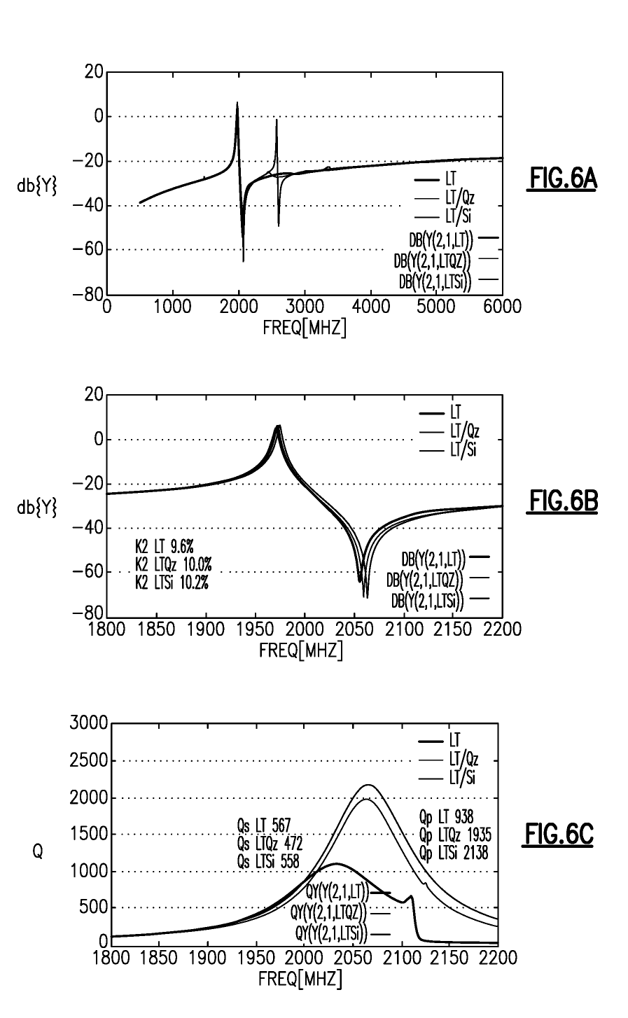

FIGS. 6A to 6C are graphs comparing characteristics of the surface acoustic wave devices of FIGS. 3A, 4, and 5. These graphs correspond to the surface acoustic wave device 10 in which the quartz substrate 12 is 42° Y-X quartz, the lithium tantalate layer 14 is 42° Y-X LT having a thickness H1 of λ (λ=2 micrometers (um)), and the IDT electrode 16 is aluminum and has a thickness h of 0.08 λ and a pitch L of λ. These graphs also correspond to the surface acoustic wave device 17 in which the lithium tantalate layer 14 is 42° Y-X LT having a thickness H1 of λ (λ=2 um) and the IDT electrode 16 is aluminum and has a thickness h of 0.08 λ and a pitch L of λ. These graphs also correspond to the surface acoustic wave device 19 in which the lithium tantalate layer 14 is 42° Y-X LT and the IDT electrode 16 is aluminum and has a thickness h of 0.08 λ (λ=2 um) and a pitch L of λ.

FIG. 6A is a graph of a frequency response for the surface acoustic wave devices of FIGS. 3A, 4, and 5. FIG. 6A shows that the surface acoustic wave device 17 has a relatively strong response for a higher order spurious mode. FIG. 6A also shows that the surface acoustic wave device 10 is relatively free of higher order spurious responses.

FIG. 6B is a graph of k² versus frequency for the surface acoustic wave devices of FIGS. 3A, 4, and 5. FIG. 6B shows that an electromechanical coupling coefficient k² of about 9.6% for the surface acoustic wave device 19, k² of about 10.0% for the surface acoustic wave device 10, and k² of about 10.2% for the surface acoustic wave device 17.

FIG. 6C is a graph of quality factor versus frequency for the surface acoustic wave devices of FIGS. 3A, 4, and 5. FIG. 6C shows a Qs of about 560 for the surface acoustic wave device 19, a Qs of about 470 for the surface acoustic wave device 10, and a Qs of about 560 for the surface acoustic wave device 17. FIG. 6C also shows a Qp of about 900 for the surface acoustic wave device 19, a Qp of about 1900 for the surface acoustic wave device 10, and a Qp of about 2100 for the surface acoustic wave device 17.

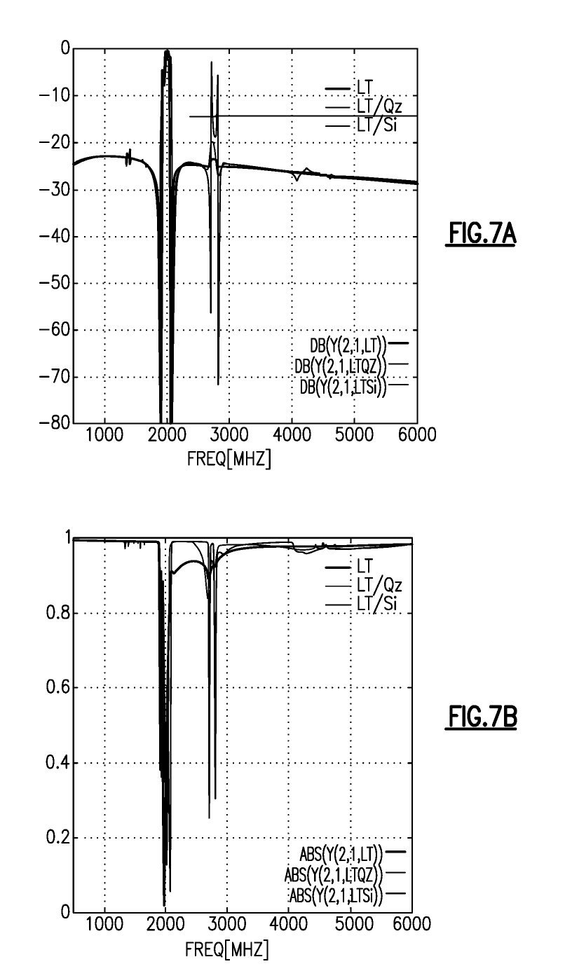

FIG. 7A is a graph of transmission characteristics for the surface acoustic wave devices of FIGS. 3A, 4, and 5 that correspond to the graphs of FIGS. 6A to 6C. FIG. 7A shows that the surface acoustic wave device 17 has a relatively strong response for a higher order spurious mode and that the surface acoustic wave device 10 is relatively free of higher order spurious responses.

FIG. 7B is a graph of reflection characteristics for the surface acoustic wave devices of FIGS. 3A, 4, and 5 that correspond to the graphs of FIGS. 6A to 6C.

FIGS. 8A, 8B, and 8C are graphs for a lithium tantalate cut angle swept for the surface acoustic wave devices of FIGS. 3A, 4, and 5. These graphs correspond to the surface acoustic wave devices corresponding to the graphs of FIGS. 6A to 6C except that lithium tantalate cut angle is varied. FIGS. 8A and 8B show that certain lithium tantalate cut angles can result in higher Qs and Qp values. FIG. 8B illustrates that an available lithium tantalate cut angle can be limited by bulk radiation. FIG. 8C shows that lower cut angles can result in a higher electromechanical coupling coefficient.

FIGS. 9A, 9B, and 9C are graphs for a quartz cut sweep for the surface acoustic wave device 10 of FIG. 3A. These graphs correspond to the surface acoustic wave device 10 corresponding to the graphs of FIGS. 6A to 6C except that quartz cut angle is varied. FIGS. 8A and 8B show that certain quartz cut angles can result in higher Qs and Qp values. These graphs indicate that quartz cut angle in a range from 20° to 52° can be desirable.

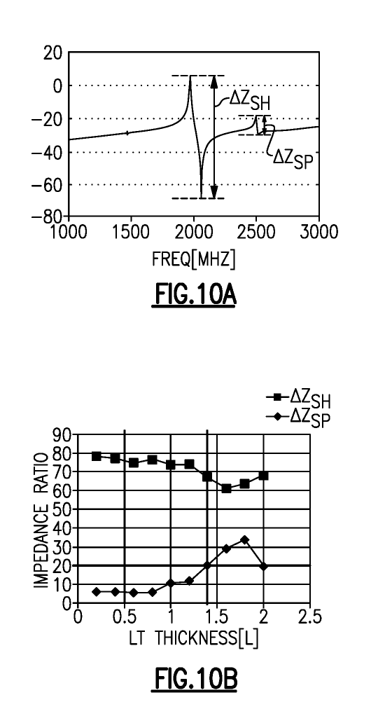

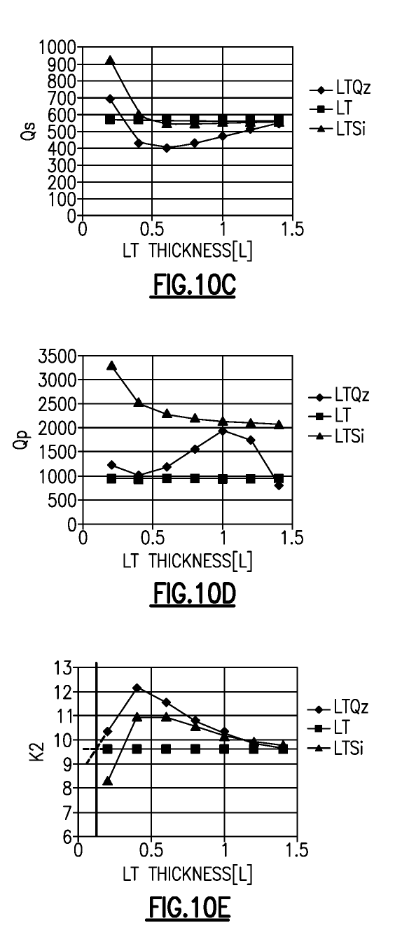

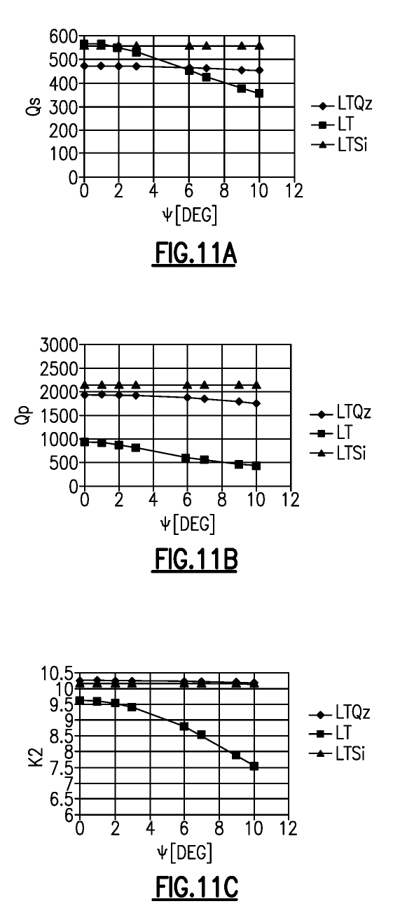

FIGS. 10A to 10E are graphs associated with a lithium tantalate thickness sweep for the surface acoustic wave device 10 of FIG. 3A. These graphs correspond to the surface acoustic wave device 10 corresponding to the graphs of FIGS. 6A to 6C except that lithium tantalate thickness H1 is varied. FIG. 10A illustrates ΔZ_{SH} and ΔZ_{SP} in a frequency response. FIG. 10B shows impedance ratios ΔZ_{SX} and ΔZ_{SP} versus thickness of the lithium tantalate layer 14. FIG. 10B indicates that a lithium tantalate thickness H1 of less than 1.4 λ can be desirable. FIG. 10C is graph of Qs versus thickness of the lithium tantalate layer of the surface acoustic wave devices of FIGS. 3A, 4, and 5. FIG. 10D is graph of Qs versus thickness of the lithium tantalate layer of the surface acoustic wave devices of FIGS. 3A, 4, and 5. FIG. 10E is graph of k² versus thickness of the lithium tantalate layer of the surface acoustic wave devices of FIGS. 3A, 4, and 5. FIG. 10E indicates that a lithium tantalate thickness H1 of at least than 0.15 λ can be desirable. Accordingly, these graphs indicate that a lithium tantalate thickness H1 in a range from 0.15 λ, to 1.4 λ, can be desirable. Above lithium tantalate thickness H1 of 1.4 λ, impedance ratios for ΔZ_{SX} and ΔZ_{SP} can be undesirable. In FIGS. 10C to 10E, plots corresponding to the surface acoustic wave device 19 of FIG. 5 with a constant thickness for the lithium tantalate layer 14 were used because the lithium tantalate layer 14 for the surface acoustic wave device 19 can be sufficiently thick to ignore the bottom reflection effect.

A thickness of the quartz substrate 12 of the surface acoustic wave device 10 of FIG. 3A can be less than, for example, 695 micrometers (um). The upper bound of the quartz substrate 12 thickness can be due to a wafer bending specification, such as the SEMI standard for a 6 inch quartz wafer. The thickness of the quartz substrate 12 can be at least λ. Accordingly, the thickness of the quartz substrate 12 can be in a range from λ to 695 um, in which λ, is a wavelength of a surface acoustic wave generated by the surface acoustic wave device 10.

FIGS. 11A to 11C are graphs associated with a lithium tantalate propagation angle sweep for the surface acoustic wave devices of FIGS. 3A, 4, and 5. These graphs correspond to the surface acoustic wave devices corresponding to the graphs of FIGS. 6A to 6C except that the propagation angle is varied. The lithium tantalate layers of FIGS. 3A, 4, and 5 can have Euler angles of φ, θ, and Ψ. The second Euler angle θ is the cut angle discussed above plus 90°. The third Euler angle Ψ is the propagation angle. FIG. 11A is a graph of Qs versus propagation angle. FIG. 11B is a graph of Qp versus propagation angle. FIGS. 11A and 11B indicate that Qs and Qp of the surface acoustic wave device 10 of FIG. 3A does not decrease too much as Ψ is rotated (e.g., increased). Accordingly, the lithium tantalate layer 14 of the surface acoustic wave device 10 of FIG. 3A can have a propagation angle Ψ that is in a range from −10° to 10°. FIG. 11C is a graph of k² versus propagation angle.

The quartz layer 12 of the surface acoustic wave device 10 of FIG. 3A can have Euler angles of φ, θ, and Ψ.The second Euler angle θ is the cut angle discussed above plus 90°. The third Euler angle Ψ is the propagation angle. Analysis of Qs, Qp, and k² of surface acoustic wave devices 10 with quartz substrates with cut angles of 40° (i.e., θ=130°) and 44° (i.e., θ=134°) indicate that it can be desirable for Ψ of the quartz substrate 12 to be in a range from −10° to 10°. Analysis of Qs, Qp, and k² of surface acoustic wave devices 10 with quartz substrates with a cut angle of 44° indicates that it can be desirable for φ of the quartz substrate 12 to be in a range from −10° to 10° in certain instances.

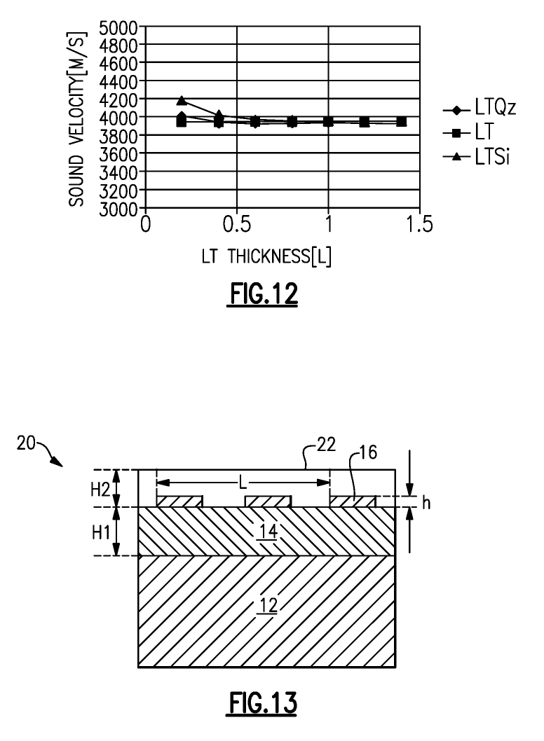

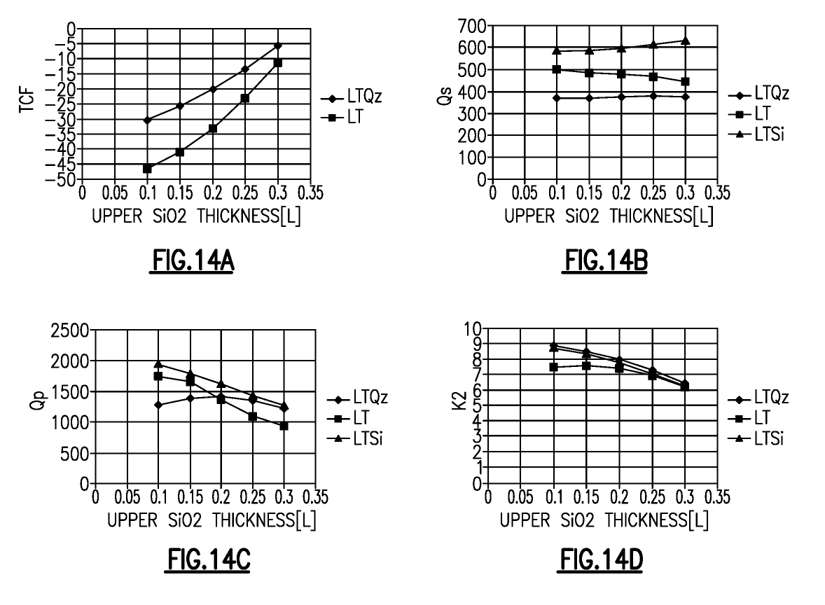

FIG. 12 is a graph of sound velocity versus lithium tantalate layer thickness for the surface acoustic wave devices of FIGS. 3A, 4, and 5. The sound velocities are in a range from 3800 meters per second to 4200 meters per second. The sound velocities correspond to a shear-horizontal (SH) mode. Accordingly, the surface acoustic wave devices discussed herein can operate in SH mode.

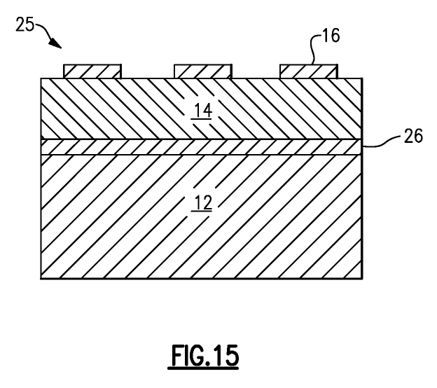

FIG. 13 is a cross sectional view of a surface acoustic wave device 20 according to an embodiment. The surface acoustic wave device 20 is similar to the surface acoustic wave device 10 of FIG. 3A except that the surface acoustic wave device 20 includes a silicon dioxide layer 22 over the IDT electrode 16. The silicon dioxide layer 22 has a thickness of H2. The silicon dioxide layer 22 can bring the TCF of the surface acoustic wave device 20 closer to zero relative to the surface acoustic wave device 10 of FIG. 3A. The surface acoustic wave device 20 can be referred to as a temperature compensated surface acoustic wave device. In some instances, a different temperature compensating layer can be implemented in place of the silicon dioxide layer 22. Such a temperature compensating layer can have a positive temperature coefficient of frequency. This can compensate for the TCF of the lithium tantalate layer 14. Alternative temperature compensating layers can include, for example, tellurium dioxide (TeO₂) and/or silicon oxyfluoride (SiOF).

FIGS. 14A to 14D are graphs of parameters of the surface acoustic wave device 20 of FIG. 13. These graphs correspond to the surface acoustic wave device 20 in which the quartz substrate 12 is 42° Y-X quartz, the lithium tantalate layer 14 is 42° Y-X LT having a thickness H1 of λ (λ=2 um), the IDT electrode 16 is aluminum and has a thickness h of 0.08 λ and a pitch L of λ, and the silicon dioxide layer 22 has a thickness of H2. These graphs include curves of parameters of the surface acoustic wave device 20 versus the thickness H2 of the silicon dioxide layer 22.

FIG. 14A is a graph of silicon dioxide thickness versus TCF for the surface acoustic wave device 20 of FIG. 13 and a similar surface acoustic wave device without a quartz substrate. FIG. 14A indicates that temperature coefficient of frequency (TCF) can be improved (i.e., closer to zero) for greater thicknesses H2 of the silicon dioxide layer 22.

FIG. 14B is a graph of silicon dioxide thickness versus Qs for the surface acoustic wave device 20 of FIG. 13 and a similar surface acoustic wave device without a quartz substrate and with a silicon substrate in place of the quartz substrate.

FIG. 14C is a graph of silicon dioxide thickness versus Qp for the surface acoustic wave device 20 of FIG. 13 and a similar surface acoustic wave device without a quartz substrate and with a silicon substrate in place of the quartz substrate.

FIG. 14D is a graph of silicon dioxide thickness versus k² for the surface acoustic wave device 20 of FIG. 13 and a similar surface acoustic wave device without a quartz substrate and with a silicon substrate in place of the quartz substrate.

FIG. 15 is a cross sectional view of a surface acoustic wave device 25 according to an embodiment. The surface acoustic wave device 25 is similar to the surface acoustic wave device 10 of FIG. 3A except that the surface acoustic wave device 25 includes an additional layer 26 disposed between the quartz substrate 12 and the lithium tantalate layer 14. The additional layer 26 can be a relatively high impedance material to enhance reflection at the LT/quartz boundary to improve quality factor. The additional layer 26 can reinforce adherence between the quartz substrate 12 and the lithium tantalate layer 14. The additional layer 26 can be, for example, an aluminum nitride (AlN) layer, a silicon nitride (SiN) layer, an aluminum oxide (AlO) layer, a silicon carbide (SiC) layer, a silicon oxynitride layer, a sapphire layer, a diamond layer, or the like.

Although certain embodiments discussed herein relate to surface acoustic wave devices that include a lithium tantalate layer, any suitable principles and advantages disclosed herein can be applied to a surface acoustic wave device that includes any other suitable lithium-based piezoelectric layer in place of a lithium tantalate layer. Lithium-based piezoelectric layers include lithium niobate (LiNbO₃) and lithium tantalate.

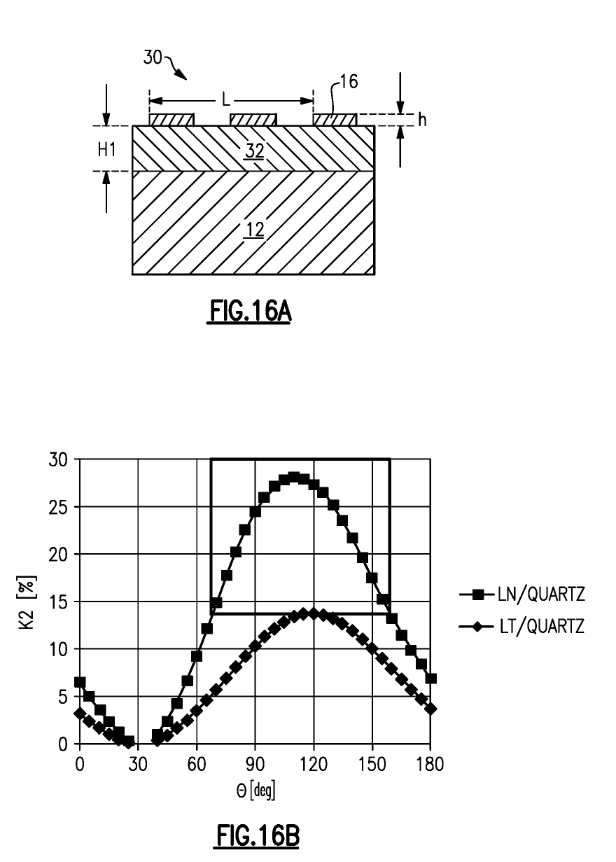

FIG. 16A is a cross sectional view of a surface acoustic wave device 30 according to an embodiment. The surface acoustic wave device 30 is similar to the surface acoustic wave device 10 of FIG. 3A except that the surface acoustic wave device 30 includes a lithium niobate layer 32 in place of a lithium tantalate layer 14.

FIG. 16B is a graph comparing electromechanical coupling coefficient k² versus cut angle of a lithium-based piezoelectric layer for the surface acoustic wave device 10 of FIG. 3A and the surface acoustic wave device 30 of FIG. 16A. The graph corresponds to surface acoustic wave devices 10 and 30 having h=0.08 λ and H1=0.3 λ. One curve on this graph corresponds to the surface acoustic wave device 10 of FIG. 3A with a lithium tantalate layer 14 having Euler angles of (0, θ, 0) and a quartz substrate 12 having Euler angles of (0, 132, 90). Another curve on this graph corresponds to the surface acoustic wave device 30 of FIG. 16A with a lithium niobate layer 32 having Euler angles of (0, θ, 0) and a quartz substrate 12 having Euler angles of (0, 132, 90). As shown in FIG. 16B, the surface acoustic wave device 30 of FIG. 16A can have a better le than the surface acoustic wave device 10 of FIG. 3A. FIG. 16B indicates that θ in a range from about 70° to 155° can be preferable in certain embodiments of the surface acoustic wave device 30.

Although certain embodiments discussed herein relate to a surface acoustic wave device that includes a quartz substrate, any suitable principles and advantages disclosed herein can be applied to a surface acoustic wave device that includes any other suitable substrate in place of the quartz substrate. The other suitable substrate can be arranged to trap an acoustic wave in a lithium-based piezoelectric layer and also allow one or more higher order spurious mode responses to leak into the other substrate.

Surface acoustic wave devices can be included in a filter. A filter that includes one or more surface acoustic wave devices can be referred to as a surface acoustic wave filter. Surface acoustic wave devices can be arranged as series resonators and shunt resonators to form a ladder filter. In some instances, a filter can include surface acoustic wave resonators and one or more other resonators (e.g., one or more bulk acoustic wave resonators, one or more Lamb wave resonators, one or more boundary acoustic wave resonators, the like, or any suitable combination thereof).

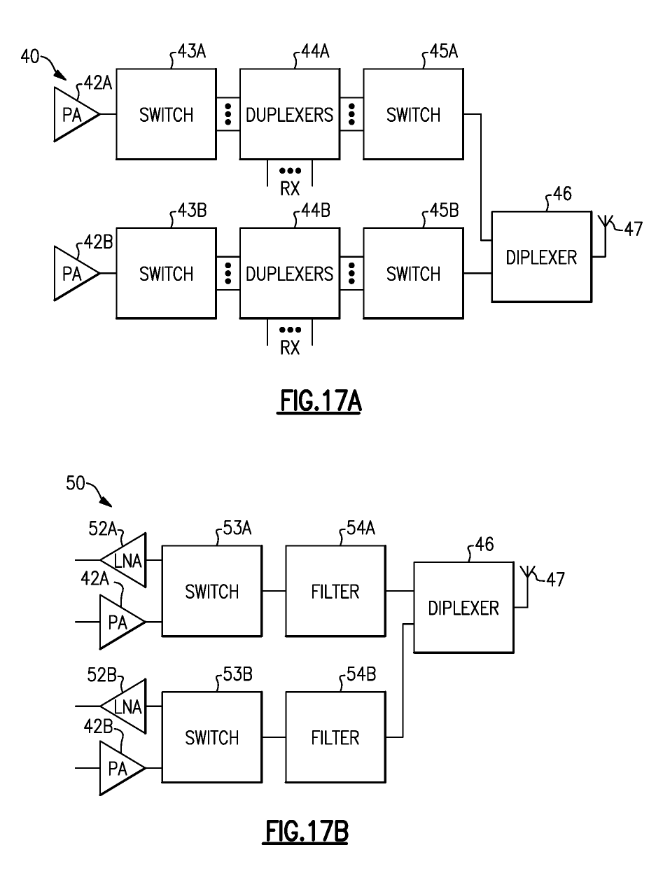

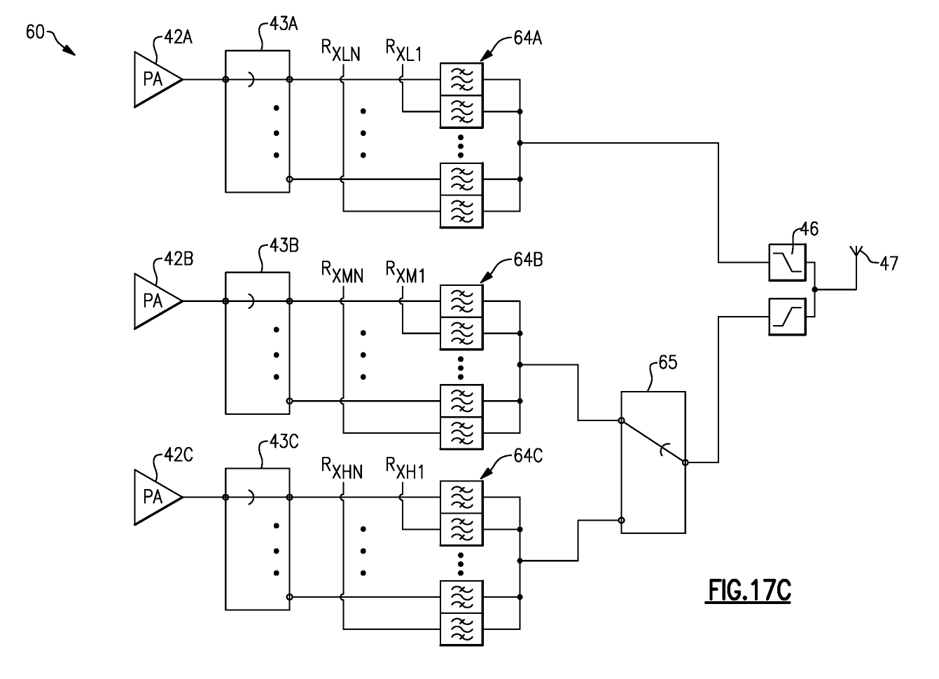

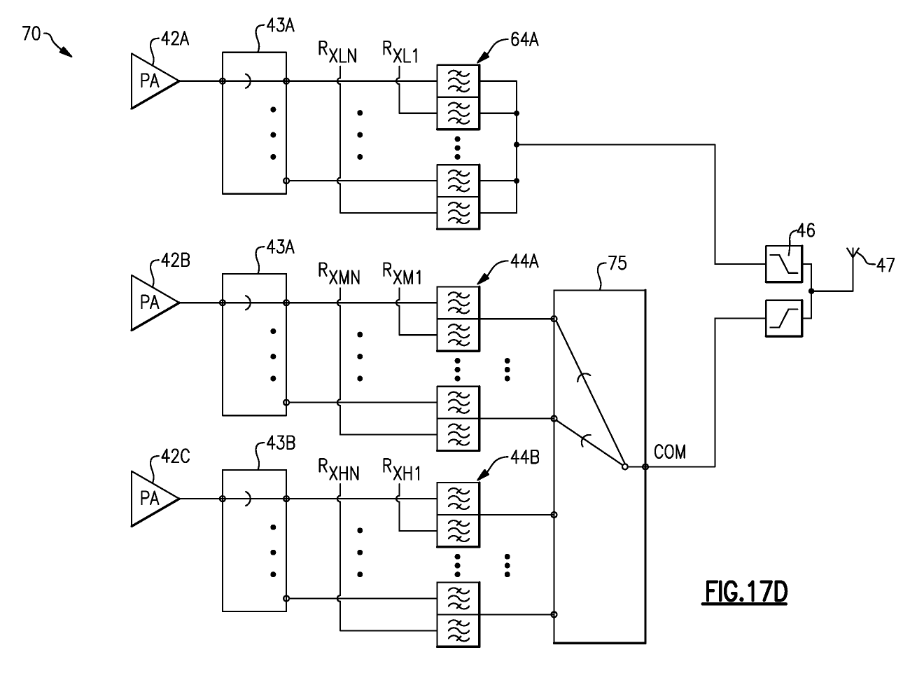

As discussed above, the surface acoustic wave devices disclosed herein can be implemented in filters configured to pass a first band of a carrier aggregation signal and to suppress a higher order spurious mode corresponding to a second band of the carrier aggregation signal. A carrier aggregation system can process a carrier aggregation signal that includes two or more carriers. For instance, a carrier aggregation system can process a carrier aggregation signal received by an antenna. As another example, a carrier aggregation system can generate a carrier aggregation signal for transmission by an antenna. Example carrier aggregation systems that can include such filters will be discussed with reference to FIGS. 17A to 17D.

FIG. 17A is a schematic diagram of a carrier aggregation system 40. The illustrated carrier aggregation system 40 includes power amplifiers 42A and 42B, switches 43A and 43B, duplexers 44A and 44B, switches 45A and 45B, diplexer 46, and antenna 47. The power amplifiers 42A and 42B can each transmit an amplified RF signal associated with a different carrier. The switch 43A can be a band select switch. The switch 43A can couple an output of the power amplifier 42A to a selected duplexer of the duplexers 44A. Each of the duplexers can include a transmit filter and receive filter. Any of the filters of the duplexers 44A and 44B can be implemented in accordance with any suitable principles and advantages discussed herein. The switch 45A can couple the selected duplexer of the duplexers 44A to the diplexer 46. The diplexer 46 can combine RF signals provided by the switches 45A and 45B into a carrier aggregation signal that is transmitted by the antenna 47. The diplexer 46 can isolate different frequency bands of a carrier aggregation signal received by the antenna 47. The diplexers 46 is an example of a frequency domain multiplexer. Other frequency domain multiplexers include a triplexer. Carrier aggregation systems that include triplexers can process carrier aggregation signals associated with three carriers. The switches 45A and 45B and selected receive filters of the duplexers 44A and 44B can provide RF signals with the isolated frequency bands to respective receive paths.

FIG. 17B is a schematic diagram of a carrier aggregation system 50. The illustrated carrier aggregation system 50 includes power amplifiers 42A and 42B, low noise amplifiers 52A and 52B, switches 53A and 53B, filters 54A and 54B, diplexer 46, and antenna 47. The power amplifiers 42A and 42B can each transmit an amplified RF signal associated with a different carrier. The switch 53A can be a transmit/receive switch. The switch 53A can couple the filter 54A to an output of the power amplifier 42A in a transmit mode and to an input of the low noise amplifier 52A in a receive mode. The filter 54A and/or the filter 54B can be implemented in accordance with any suitable principles and advantages discussed herein. The diplexer 46 can combine RF signals from the power amplifiers 42A and 42B provided by the switches 53A and 53B into a carrier aggregation signal that is transmitted by the antenna 47. The diplexer 46 can isolate different frequency bands of a carrier aggregation signal received by the antenna 47. The switches 53A and 53B and the filters 54A and 54B can provide RF signals with the isolated frequency bands to respective low noise amplifiers 52A and 52B.

FIG. 17C is a schematic diagram of a carrier aggregation system 60 that includes multiplexers in signal paths between power amplifiers and an antenna. The illustrated carrier aggregation system 60 includes a low band path, a medium band path, and a high band path. In certain applications, a low band path can process radio frequency signals having a frequency of less than 1 GHz, a medium band path can process radio frequency signals having a frequency between 1 GHz and 2.2 GHz, and a high band path can process radio frequency signals having a frequency above 2.2 GHz.

A diplexer 46 can be included between RF signal paths and an antenna 47. The diplexer 46 can frequency multiplex radio frequency signals that are relatively far away in frequency. The diplexer 46 can be implemented with passive circuit elements having a relatively low loss. The diplexer 46 can combine (for transmit) and separate (for receive) carriers of carrier aggregation signals.

As illustrated, the low band path includes a power amplifier 42A configured to amplify a low band radio frequency signal, a band select switch 43A, and a multiplexer 64A. The band select switch 43A can electrically connect the output of the power amplifier 42A to a selected transmit filter of the multiplexer 64A. The selected transmit filter can be a band pass filter with pass band corresponding to a frequency of an output signal of the power amplifier 42A. The multiplexer 64A can include any suitable number of transmit filters and any suitable number of receive filters. One or more of the transmit filters and/or one or more of the receive filters can be implemented in accordance with any suitable principles and advantages discussed herein. The multiplexer 64A can have the same number of transmit filters as receive filters. In some instances, the multiplexer 64A can have a different number of transmit filters than receive filters.

As illustrated in FIG. 17C, the medium band path includes a power amplifier 42B configured to amplify a medium band radio frequency signal, a band select switch 43B, and a multiplexer 64B. The band select switch 43B can electrically connect the output of the power amplifier 42B to a selected transmit filter of the multiplexer 64B. The selected transmit filter can be a band pass filter with pass band corresponding to a frequency of an output signal of the power amplifier 42B. The multiplexer 64B can include any suitable number of transmit filters and any suitable number of receive filters. One or more of the transmit filters and/or one or more of the receive filters can be implemented in accordance with any suitable principles and advantages discussed herein. The multiplexer 64B can have the same number of transmit filters as receive filters. In some instances, the multiplexer 64B can have a different number of transmit filters than receive filters.

In the illustrated carrier aggregation system 60, the high band path includes a power amplifier 42C configured to amplify a high band radio frequency signal, a band select switch 43C, and a multiplexer 64C. The band select switch 43C can electrically connect the output of the power amplifier 42C to a selected transmit filter of the multiplexer 64C. The selected transmit filter can be a band pass filter with pass band corresponding to a frequency of an output signal of the power amplifier 42C. The multiplexer 64C can include any suitable number of transmit filters and any suitable number of receive filters. One or more of the transmit filters and/or one or more of the receive filters can be implemented in accordance with any suitable principles and advantages discussed herein. The multiplexer 64C can have the same number of transmit filters as receive filters. In some instances, the multiplexer 64C can have a different number of transmit filters than receive filters.

A select switch 65 can selectively provide a radio frequency signal from the medium band path or the high band path to the diplexer 46. Accordingly, the carrier aggregation system 60 can process carrier aggregation signals with either a low band and high band combination or a low band and medium band combination.

FIG. 17D is a schematic diagram of a carrier aggregation system 70 that includes multiplexers in signal paths between power amplifiers and an antenna. The carrier aggregation system 70 is like the carrier aggregation system 60 of FIG. 17C, except that the carrier aggregation system 70 includes switch-plexing features. Switch-plexing can be implemented in accordance with any suitable principles and advantages discussed herein.

Switch-plexing can implement on-demand multiplexing. Some radio frequency systems can operate in a single carrier mode for a majority of time (e.g., about 95% of the time) and in a carrier aggregation mode for a minority of the time (e.g., about 5% of the time). Switch-plexing can reduce loading in a single carrier mode in which the radio frequency system can operate for the majority of the time relative to a multiplexer that includes filters having a fixed connection at a common node. Such a reduction in loading can be more significant when there are a relatively larger number of filters included in multiplexer.

In the illustrated carrier aggregation system 70, duplexers 64B and 64C are selectively coupled to a diplexer 46 by way of a switch 75. The switch 75 is configured as a multi-close switch that can have two or more throws active concurrently. Having multiple throws of the switch 75 active concurrently can enable transmission and/or reception of carrier aggregation signals. The switch 75 can also have a single throw active during a single carrier mode. As illustrated, each duplexer of the duplexers 44A coupled to separate throws of the switch 75. Similarly, the illustrated duplexers 44B include a plurality of duplexers coupled to separate throws of the switch 75. Alternatively, instead of duplexers being coupled to each throw the switch 75 as illustrated in FIG. 17D, one or more individual filters of a multiplexer can be coupled to a dedicated throw of a switch coupled between the multiplexer and a common node. For instance, in some applications, such a switch could have twice as many throws as the illustrated switch 75.

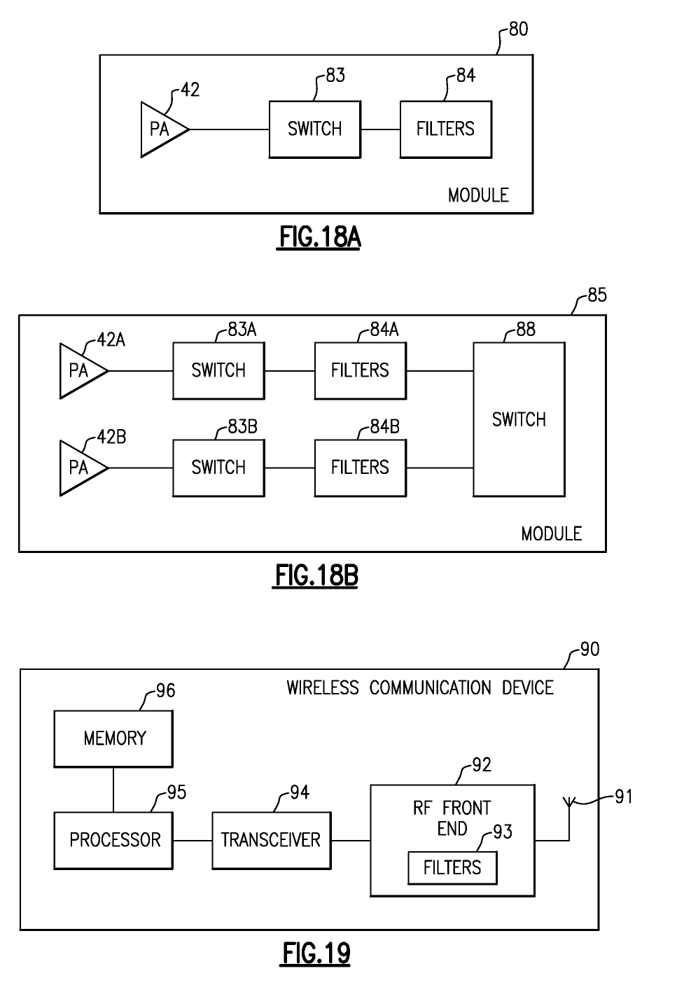

The filters discussed herein can be implemented in a variety of packaged modules. Some example packaged modules will now be discussed in which any suitable principles and advantages of the filters discussed herein can be implemented. FIGS. 18A and 18B are schematic block diagrams of illustrative packaged modules according to certain embodiments.

FIG. 18A is a schematic block diagram of a module 80 that includes a power amplifier 42, a switch 83, and filters 84 in accordance with one or more embodiments. The module 80 can include a package that encloses the illustrated elements. The power amplifier 42, a switch 83, and filters 84 can be disposed on a common packaging substrate. The packaging substrate can be a laminate substrate, for example. The switch 83 can be a multi-throw radio frequency switch. The switch 83 can electrically couple an output of the power amplifier 42 to a selected filter of the filters 84. The filters 84 can include any suitable number of surface acoustic wave filters. One or more filters of the filters 84 can be implemented in accordance with any suitable principles and advantages disclosed herein.

FIG. 18B is a schematic block diagram of a module 85 that includes power amplifiers 42A and 42B, switches 83A and 83B, and filters 84A and 84B in accordance with one or more embodiments, and an antenna switch 88. The module 85 is like the module 80 of FIG. 18A, except the module 85 includes an additional RF signal path and the antenna switch 88 arranged to selectively couple a signal from the filters 84A or the filters 84B to an antenna node. One or more filters of the filters 84A and/or 84B can be implemented in accordance with any suitable principles and advantages disclosed herein. The additional RF signal path includes an additional power amplifier 42B, and additional switch 83B, and additional filters 84B. The different RF signal paths can be associated with different frequency bands and/or different modes of operation (e.g., different power modes, different signaling modes, etc.).

FIG. 19 is a schematic block diagram of a wireless communication device 90 that includes filters 93 in accordance with one or more embodiments. One or more surface acoustic wave filters of the filters 93 can be implemented in accordance with any suitable principles and advantages disclosed herein. The wireless communication device 90 can be any suitable wireless communication device. For instance, a wireless communication device 90 can be a mobile phone, such as a smart phone. As illustrated, the wireless communication device 90 includes an antenna 91, an RF front end 92, a transceiver 94, a processor 95, and a memory 96. The antenna 91 can transmit RF signals provided by the RF front end 92. Such RF signals can include carrier aggregation signals. The antenna 91 can provide received RF signals to the RF front end 92 for processing. Such RF signals can include carrier aggregation signals.

The RF front end 92 can include one or more power amplifiers, one or more low noise amplifiers, RF switches, receive filters, transmit filters, duplex filters, multiplexers, frequency multiplexing circuits, or any combination thereof. The RF front end 92 can transmit and receive RF signals associated with any suitable communication standards. Any of the surface acoustic wave devices and/or filters disclosed herein can be implemented in the filters 93 of the RF front end 92.

The transceiver 94 can provide RF signals to the RF front end 92 for amplification and/or other processing. The transceiver 94 can also process an RF signal provided by a low noise amplifier of the RF front end 92. The transceiver 94 is in communication with the processor 95. The processor 95 can be a baseband processor. The processor 95 can provide any suitable base band processing functions for the wireless communication device 90. The memory 96 can be accessed by the processor 95. The memory 96 can store any suitable data for the wireless communication device 90.

Any of the principles and advantages discussed herein can be applied to other suitable systems (e.g., carrier aggregation systems), modules, chips, surface acoustic wave devices, filters, duplexers, multiplexers, wireless communication devices, and methods not just to the systems, modules, filters, multiplexers, wireless communication devices, and methods described above. The elements and operations of the various embodiments described above can be combined to provide further embodiments. Any of the principles and advantages discussed herein can be implemented in association with radio frequency circuits configured to process signals having a frequency in a range from about 30 kHz to 300 GHz, such as in a range from about 450 MHz to 8.5 GHz. For instance, any of the filters discussed herein can filter signals having a frequency in a range from about 30 kHz to 300 GHz, such as in a range from about 450 MHz to 8.5 GHz.

Aspects of this disclosure can be implemented in various electronic devices. Examples of the electronic devices can include, but are not limited to, consumer electronic products, parts of the consumer electronic products such as chips and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a vehicular electronics system such as an automotive electronics system, a microwave, a refrigerator, a stereo system, a digital music player, a camera such as a digital camera, a portable memory chip, a household appliance, etc. Further, the electronic devices can include unfinished products.

Conditional language used herein, such as, among others, “can,” “could,” “might,” “may,” “e.g.,” “for example,” “such as” and the like, unless specifically stated otherwise or otherwise understood within the context as used, is generally intended to convey that certain embodiments include, while other embodiments do not include, certain features, elements and/or states. The word “coupled,” as generally used herein, refers to two or more elements that may be either directly coupled to each other, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application.

While certain embodiments have been described, these embodiments have been presented by way of example only and are not intended to limit the scope of the disclosure. Indeed, the novel devices, chips, methods, apparatus, and systems described herein may be embodied in a variety of other forms. Furthermore, various omissions, substitutions and changes in the form of the methods, apparatus, and systems described herein may be made without departing from the spirit of the disclosure. For example, circuit blocks described herein may be deleted, moved, added, subdivided, combined, and/or modified. Each of these circuit blocks may be implemented in a variety of different ways. The accompanying claims and their equivalents are intended to cover any such forms or modifications as would fall within the scope and spirit of the disclosure.

What is claimed is:

1. A filter for a carrier aggregation system, the filter comprising a surface acoustic wave device that includes a quartz substrate, an interdigital transducer electrode, and a lithium-based piezoelectric layer positioned between the quartz substrate and the interdigital transducer electrode, the surface acoustic wave device being configured to suppress a higher order spurious mode corresponding to a second band of a carrier aggregation signal, and the filter being configured to pass a first band of the carrier aggregation signal.

2. The filter of claim 1 wherein the quartz substrate has a cut angle in a range from 20° to 52°.

3. The filter of claim 1 wherein the lithium-based piezoelectric layer is a lithium tantalate layer.

4. The filter of claim 3 wherein the surface acoustic wave device is configured to generate a surface acoustic wave having a wavelength of λ and a thickness of the lithium tantalate layer is in a range from 0.15 λ to 1.4 λ.

5. The filter of claim 1 wherein the filter is a transmit filter, the first band is a transmit band, and the second band is a receive band.

6. The filter of claim 1 wherein the filter is a receive filter, the first band is a receive band, and the second band is a transmit band.

7. The filter of claim 1 wherein the filter is configured to suppress another higher order spurious mode corresponding to a third band of the carrier aggregation signal.

8. The filter of claim 1 wherein the lithium-based piezoelectric layer is a lithium tantalate layer having a cut angle in a range from 10° to 50°.

9. The filter of claim 1 wherein the surface acoustic wave device is configured to operate in a shear-horizontal mode.

10. The filter of claim 1 wherein the surface acoustic wave device has a sound velocity in a range from 3,800 meters per second to 4,200 meters per second.

11. The filter of claim 1 wherein the lithium-based piezoelectric layer is bonded to the quartz substrate.

12. The filter of claim 1 wherein the surface acoustic wave device further includes an additional layer disposed between the lithium-based piezoelectric layer and the quartz substrate, the additional layer configured to cause a quality factor of the surface acoustic wave device to be increased.

13. A filter assembly for a carrier aggregation system, the filter assembly comprising:
a first filter including a surface acoustic wave device that includes a quartz substrate, an interdigital transducer electrode, and a lithium-based piezoelectric layer positioned between the quartz substrate and the interdigital transducer electrode, the surface acoustic wave device being configured to suppress a higher order spurious mode corresponding to a second band of a carrier aggregation signal, and the first filter being configured to pass a first band of the carrier aggregation signal; and
a second filter configured to pass a second band of the carrier aggregation signal.

14. The filter assembly of claim 13 wherein the first filter is a transmit filter and the second filter is a receive filter.

15. The filter assembly of claim 13 wherein the first filter is a receive filter and the second filter is a transmit filter.

16. The filter assembly of claim 13 wherein the filter assembly includes a multiplexer that includes the first filter and the second filter.

17. A carrier aggregation system comprising:
a frequency multiplexing circuit having a terminal at which a carrier aggregation signal is provided; and
a multiplexer in communication with the frequency multiplexing circuit, the multiplexer including filters coupled to a common node, the filters including a first filter configured to pass a first band of the carrier aggregation signal, the first filter including a surface acoustic wave device that includes a quartz substrate, an interdigital transducer electrode, and a lithium-based piezoelectric layer positioned between the quartz substrate and the interdigital transducer electrode, the surface acoustic wave device being configured to suppress a higher order spurious mode corresponding to a second band of the carrier aggregation signal.

18. The carrier aggregation system of claim 17 wherein the frequency multiplexing circuit is a diplexer.

19. The carrier aggregation system of claim 17 wherein the multiplexer is a duplexer.

20. The carrier aggregation system of claim 17 further comprising a power amplifier and a switch coupled between the power amplifier and the first filter.
